(19) United States
(12) Patent Application Publication
(10) Pub. No.: US 2009/0297426 A1
(43) Pub. Date: Dec. 3, 2009

(54) SILICON WAFER

(75) Inventors: Takeo KATOH, Tokyo (JP); Kazushige TAKAISHI, Tokyo (JP)

Correspondence Address: GREENBLUM & BERNSTEIN, P.L.C., 1950 ROLAND CLARKE PLACE, RESTON, VA, 20191, US

(73) Assignee: SUMCO CORPORATION, Tokyo (JP)

(21) Appl. No.: 12/475,840

(22) Filed: Jun. 1, 2009

(30) Foreign Application Priority Data
Jun. 3, 2008 (JP) 2008-146226

(51) Int. Cl. C30B 29/06; C30B 15/00

(52) U.S. Cl. 423/325; 117/20

(57) ABSTRACT

When a monocrystal is pulled up, an additive element such as boron is added to a molten silicon, and a pulling-up condition is such that a solid solution oxygen concentration is equal to or higher than 2×10^{18 atoms/cm}³ and a chemical compound precipitation area of silicon and the additive element is formed.

### CROSS-REFERENCE TO RELATED APPLICATIONS

The present application claims priority under 35 U.S.C. §119 of Japanese Application No. 2008-146226, filed on Jun. 3, 2008, the disclosure of which is expressly incorporated by reference herein in its entirety.

### BACKGROUND OF THE INVENTION

1. Field of the Invention

The present invention relates to a silicon wafer, and more specifically, relates to a silicon wafer that has a higher rigidity and is harder to sag than a conventional wafer when it is simple-supported in a horizontal state.

2. Description of Related Art

In a device process, during exposure, light from an exposure source is irradiated on a pattern formed on a mask (reticle) through a stepper (reduced-projection type exposure device), for example, and the light passing through the pattern is reduced by a reduced-projection lens before being transferred onto a surface of a silicon wafer coated with a photoresist (see, for example, Japanese Patent Laid-open Publication No. 2005-228978). As shown in FIG. 4, a silicon wafer 100 shipped out of a wafer manufacturing facility is a CZ (Czochralski type) wafer having a diameter of 300 mm, a thickness of 775 μm, a solid solution oxygen concentration of from 5×10¹⁷ to 11×10¹⁷ atoms/cm³ and a Young's modulus of about 110 GPa. During exposure, the silicon wafer 100 is simple-supported at its periphery by 6 support pins 101 arranged on a wafer stage along a circumferential direction of the stage (circumferential direction of the wafer) at every 60° in a state of being acted upon only by its own weight, the wafer stage being disposed at a bottom part of a stepper.

As described above, the conventional silicon wafer 100 is a CZ wafer having a solid solution oxygen concentration of from 5×10¹⁷ to 11×10^{17 atoms/cm}³ and a Young's modulus of about 110 GPa. Therefore, in the case of a next generation silicon wafer having a diameter of equal to or larger than 450 mm, for example, when a wafer is simple-supported at its periphery on the wafer stage of the stepper, sag occurs to a front surface 100a and a rear surface 100b (solid lines in FIG. 4) of the horizontally disposed silicon wafer 100 (dashed-two-dotted lines in FIG. 4) under the wafer's own weight. As a result, decrease in pattern resolution and decrease in depth of focus occur at the periphery of the wafer, and high pattern accuracy cannot be ensured. SUMMARY OF THE INVENTION

As a result of an extensive research, the inventors focused on the rigidity (Young's modulus) of a silicon wafer. More specifically, the inventors noticed that, when a silicon monocrystal is pulled up by using the Czochralski method, by making the solid solution oxygen concentration higher than a conventional wafer and adding a certain amount of an additive element such as boron, carbon or nitrogen, the rigidity of a silicon wafer is increased as compared to a conventional wafer so that the silicon wafer is harder to sag when it is simple-supported. This finding resulted in a non-limiting feature of the present invention.

A non-limiting advantage of this invention provides a silicon wafer that has a higher rigidity and is harder to sag than a conventional wafer.

A first aspect of the present invention provides a silicon wafer fabricated from a silicon monocrystal pulled up from a molten silicon by using the Czochralski method, the molten silicon being added with an additive element. The silicon wafer has a solid solution oxygen concentration of equal to or higher than 2×10¹⁸ atoms/cm³ and chemical compound precipitation areas formed by precipitation of a chemical compound of silicon and the additive element.

According to the first aspect of the present invention, when a silicon monocrystal is pulled up by using the Czochralski method, a certain amount of an additive element is added and the pulling-up condition is such that a solid solution oxygen concentration is equal to or higher than 2×10¹⁸ atoms/cm³ and chemical compound precipitation areas are formed by precipitation of a chemical compound of silicon and the additive element. Thereby, a silicon monocrystal is grown containing chemical compound precipitation areas of silicon and the additive element. The silicon monocrystal is then wafer-processed. By doing so, a silicon wafer is obtained having a solid solution oxygen concentration equal to or higher than 2×10¹⁸ atoms/cm³ and chemical compound precipitation areas of silicon and the additive element.

Due to the addition of an additive element, distortion of the crystal lattice of the silicon increases as compared to a pure silicon (silicon containing no other elements). Therefore, the silicon (silicon crystal) has a larger slip resistance and a larger deformation resistance. This phenomenon becomes more notable as the additive amount of the additive element increases. For this reason, a silicon monocrystal is grown having a solid solution oxygen concentration of equal to or higher than 2×10¹⁸ atoms/cm³ and containing chemical compound precipitation areas of silicon and the additive element, and a silicon wafer is obtained from this silicon monocrystal. As a result, the Young's modulus of the silicon wafer increases to 140-160 GPa, and thus, the silicon wafer has a higher rigidity as compared to a conventional silicon wafer (having a solid solution oxygen concentration of 5×10¹⁷-11×10¹⁷ atoms/cm³ and a Young's modulus of 100-120 GPa). Since chemical compound precipitation areas are formed in the silicon wafer, when thermal stress occurs, slip can be reduced by effects such as dislocation pinning. Further, gettering sites are formed, thereby providing a pollution control function in a device process.

A monocrystalline silicon wafer, a polycrystalline silicon wafer or the like may be used as a silicon wafer. Surfaces of the silicon wafer are mirror finished. The diameter of the silicon wafer is, for example, 200 mm, 300 mm, 450 mm or the like. As an “additive element”, for example, boron, carbon, nitrogen, oxygen, phosphorus, arsenic or the like may be used. When solid solution oxygen concentration is below 2×10¹⁸ atoms/cm³, significant effect cannot be obtained. A favorable solid solution oxygen concentration is 3×10¹⁸-10×10^{18 atoms/cm}³. When the solid solution oxygen concentration is in this range, there are no particular difficulties in fabrication.

An additive amount of an additive element (dopant concentration) varies with the type of the additive element and the like. As a method for adding an additive element to silicon, in the case where the additive element is a solid, the additive element may be put into a molten silicon in a crucible when a semiconductor monocrystal is pulled up by using the Czochralski method, for example. And, in the case where the additive element is a gas, the additive element gas may be used as a gas in the chamber of the pulling apparatus when a semiconductor monocrystal is pulled up by using the Czochralski method.

The “chemical compound of silicon and an additive element” may be a silicon boride, a silicon nitride, a silicon carbide, a silicon oxide, or the like. The “chemical compound precipitation area” means a precipitation portion of a chemical compound that is formed in a silicon wafer and is separated from silicon by an interface. The chemical compound precipitation area has a diameter (grain diameter) of equal to or larger than 2 nm. When it is below 2 nm, sufficient effect of the present invention cannot be obtained. The desirable size of the chemical compound precipitation area is 10 nm -1 μm. When the size of the chemical compound precipitation area is in this range, sufficient effect of the present invention can be obtained, and formation of a network-like dislocation can be prevented.

It is desirable that the Young's modulus of the silicon wafer is 120-500 GPa. When it is below 120 GPa, there is no notable difference as compared to a conventional silicon wafer. When it is above 500 GPa, there is no change in the amount of sagging. Favorable Young's modulus of a silicon wafer is 150-300 GPa. When the Young's modulus of the silicon wafer is in this range, the effect of the present invention can be sufficiently obtained, and there are fewer problems in the fabrication process.

In the case where boron is used as an additive element, it is favorable that a boron concentration in a silicon wafer is equal to or higher than 1×10²⁰ atoms/cm³. When a boron concentration is below 1×10²⁰ atoms/cm³, notable effect cannot be obtained. A particularly favorable boron concentration is 1×10²⁰-5×10^{0 atoms/cm}³. When a boron concentration is in this range, sufficient effect of the present invention can be obtained, and there are fewer problems in fabrication.

In the case where carbon is used as an additive element, it is favorable that a carbon concentration in a silicon wafer is 1×10¹²-1×10¹⁵ atoms/cm³. When a carbon concentration is below 1×10¹² atoms/cm³, notable effect cannot be obtained. A particularly favorable carbon concentration is 1×10¹³-1×10¹⁴ atoms/cm³. When a carbon concentration is in this range, sufficient effect of the present invention can be obtained, and there are fewer problems in fabrication. In the case where nitrogen is used as an additive element, a silicon wafer has a nitrogen concentration of 1×10¹⁴-1×10¹⁷ atoms/cm³. When a nitrogen concentration is below 1×10¹⁴ atoms/cm³, notable effect cannot be obtained. A particularly favorable carbon concentration is 1×10¹⁵-1×10¹⁶ atoms/cm³. When a nitrogen concentration is in this range, sufficient effect of the present invention can be obtained, and there are fewer problems in fabrication.

A second aspect of the present invention provides a silicon wafer fabricated from a silicon monocrystal pulled up from a molten silicon by using the Czochralski method, the molten silicon being added with an additive element. The silicon wafer has a solid solution oxygen concentration of equal to or higher than 2×10¹⁸ atoms/cm³ and is formed of a solid solution of silicon and the additive element.

According to the second aspect of the present invention, when a silicon monocrystal is pulled up by using the Czochralski method, a certain amount of an additive element is added and the pulling-up condition is such that a solid solution oxygen concentration is equal to or higher than 2×10¹⁸ atoms/cm³ and a solid solution of silicon and the additive element is formed. Thereby, a silicon monocrystal composed of a solid solution of silicon and the additive element is grown. The silicon monocrystal is then wafer-processed. By doing so, a silicon wafer is obtained from the solid solution, having a Young's modulus of 150-300 GPa. The wafer so obtained has a higher rigidity as compared to a conventional silicon wafer. Further, since the silicon wafer is formed of a solid solution of silicon and the additive element, there are fewer bulk defects.

A solid solution may be a substitution solid solution or an interstitial solid solution. Further, a solid solution may be a primary solid solution that has the same crystal structure as component metal, or a secondary solid solution that has a different crystal structure as component metal. An additive amount of an additive element (dopant concentration) varies with the type of the additive element. It is desirable that the Young's modulus of the silicon wafer is 120-500 GPa. When it is below 120 GPa, there is no notable difference as compared to a conventional silicon wafer. When it is above 500 GPa, there is no significant change in the amount of sagging. Favorable Young's modulus of a silicon wafer is 150-300 GPa. When the Young's modulus of the silicon wafer is in this range, the effect of the present invention can be sufficiently obtained, and there are fewer difficulties in the fabrication process.

In the case where boron is used as an additive element, it is favorable that a boron concentration in a silicon wafer is equal to or higher than 1×10²⁰ atoms/cm³. When a boron concentration is below 1×10²⁰ atoms/cm³, notable effect cannot be obtained. A particularly favorable boron concentration is 1×10²⁰-5×10²⁰ atoms/cm³. When a boron concentration is in this range, sufficient effect of the present invention can be obtained, and there are fewer problems in fabrication.

In the case where carbon is used as an additive element, it is favorable that a carbon concentration in a silicon wafer is 1×10¹²-1×10¹⁵ atoms/cm³. When a carbon concentration is below 1×10¹² atoms/cm³, notable effect cannot be obtained. A particularly favorable carbon concentration is 1×10¹³-1×10¹⁴ atoms/cm³. When a carbon concentration is in this range, sufficient effect of the present invention can be obtained, and there are fewer problems in fabrication.

In the case where nitrogen is used as an additive element, it is favorable that a nitrogen concentration in a silicon wafer is 1×10¹⁴-1×10^{17 atoms/cm}³. When a nitrogen concentration is below 1×10¹⁴ atoms/cm³, notable effect cannot be obtained. A particularly favorable carbon concentration is 1×10¹⁵-1×10¹⁶ atoms/cm³. When a nitrogen concentration is in this range, sufficient effect of the present invention can be obtained, and there are fewer problems in fabrication.

### BRIEF DESCRIPTION OF THE DRAWINGS

The present invention is further described in the detailed description which follows, in reference to the noted plurality of drawings by way of non-limiting examples of exemplary embodiments of the present invention, in which like reference numerals represent similar parts throughout the several views of the drawings, and wherein:

FIG. 1 is a cross-sectional view showing a semiconductor wafer according to a first embodiment of the present invention;

FIG. 2 is a cross-sectional view showing the semiconductor wafer according to the first embodiment of the present invention in a simple-supported state;

FIG. 3 is a cross-sectional view showing a semiconductor wafer according to a second embodiment of the present invention in a simple-supported state; and

FIG. 4 is a cross-sectional view showing a conventional semiconductor wafer in a state before being simple-supported and in a state after being simple-supported.

### DETAILED DESCRIPTION OF THE INVENTION

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description is taken with the drawings making apparent to those skilled in the art how the forms of the present invention may be embodied in practice.

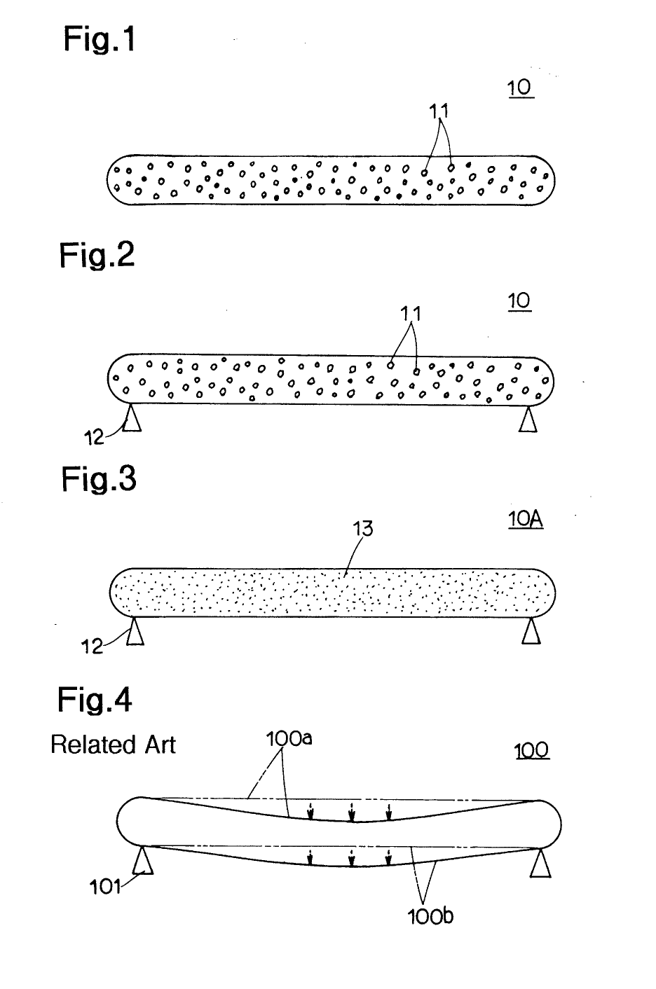

The embodiments of the present invention are explained in detail in the following. In FIG. 1, reference numeral 10 represents a silicon wafer according to the first embodiment of the present invention. The silicon wafer 10 is a monocrystalline CZ wafer. The monocrystalline CZ wafer is fabricated as follows. A silicon monocrystal is pulled up by using the Czochralski method from a molten silicon containing boron (additive element) so that chemical compound precipitation areas 11 of silicon and boron are formed in silicon. Next, the silicon monocrystal is wafer-processed. A silicon wafer, with a surface (device forming side) being mirror-finished, has a diameter of 450 mm, a thickness of 925 μm, a resistivity of 10 Ω·cm, and a solid solution oxygen concentration of 3×10^{18 atoms/cm}³.

The following explains a growth method of a silicon monocrystal, which serves as a raw material for the silicon wafer 10. A silicon raw material for crystals, which is mixed with boron in advance so as to have a boron concentration of 2×10²⁰ atoms/cm³, is put in a quartz crucible in a chamber. The pressure in the chamber is then reduced to 25 Torr, and an argon gas is flowed into the chamber. In this state, the material in the quartz crucible is melted by a heater, and a molten silicon containing boron is formed.

Thereafter, a seed crystal attached to the lower end of a pull shaft is immersed into the molten silicon, and the pull shaft is pulled up along an axial direction while the quartz crucible and the pull shaft being rotated along opposite directions from each other. Thereby, a silicon monocrystal is grown below the seed crystal. During pulling up, the silicon monocrystal near the fluid level is constantly filmed by using a CCD camera through a window formed on the chamber. Based on data of the film, a diameter of the silicon monocrystal right after pulling up is measured by using a diameter measuring function of an image processor. Based on the result of the measurement, silicon monocrystal pulling-up speed and silicon monocrystal heating temperature by the heater are suitably controlled. Specifically, the pulling-up speed and heating temperature are controlled such that the silicon monocrystal has a solid solution oxygen concentration of 3×10¹⁸ atoms/cm³ and contains chemical compound precipitation areas 11 of silicon boride at a density of 1×10¹⁰ per cm³, the diameters of chemical compound precipitation areas 11 being equal to or larger than 0.1 μm. The silicon boride (such as SiB₄ and SiB₆) is a chemical compound of silicon and boron. The density of the chemical compound precipitation areas 11 is measured by using a MO601 of Mitsui Mining & Smelting Co., Ltd. In a wafer-processing operation with respect to a straight body portion of the obtained silicon monocrystal, periphery grinding, block cutting, slicing and polishing are performed, and a silicon wafer having a diameter of 450 mm is fabricated.

The silicon wafer so fabricated is next transferred to a device process, in which devices are formed on a surface of the wafer. During exposure of the device process, the silicon wafer 10 is supported at its periphery by 6 support pins 12 arranged on a wafer stage along a circumferential direction of the wafer stage (circumferential direction of the silicon wafer) at every 60° in a simple-supported state of without being acted upon by an external force, the wafer stage being disposed at a bottom part of a stepper (FIG. 2). Light radiated from an exposure source passes through a pattern formed on a mask and is reduced by a reduced-projection lens before irradiating a surface of the silicon wafer 10, which is coated with a photoresist, thereby transferring the pattern. The silicon wafer 10 is fabricated from the silicon monocrystal pulled up under the above-described condition, and has a diameter of 450 mm and a thickness of 925 μm. As a result, the Young's modulus of the silicon wafer 10 is 150 GPa. The “above-described condition” is a condition such that the solid solution oxygen concentration of the silicon monocrystal is 3×10¹⁸ atoms/cm³ and chemical compound precipitation areas 1 of silicon boride of diameters equal to or larger than 0.1 μm are formed in the silicon at a density of 1×10¹⁰ per cm³.

Due to the addition of an additive element such as boron, distortion of the crystal lattice of the silicon increases as compared to a pure silicon. Therefore, the silicon (crystal) has a larger slip resistance and a larger deformation resistance. This phenomenon becomes more notable as the additive amount of the additive element increases. For this reason, a silicon monocrystal is grown having a solid solution oxygen concentration of 3×10¹⁸ atoms/cm³ and containing the chemical compound precipitation areas 11, and a silicon wafer is obtained from this silicon monocrystal. As a result, the Young's modulus of the silicon wafer increases to 200 GPa, and thus, the silicon wafer has a higher rigidity as compared to a conventional silicon wafer (having a solid solution oxygen concentration of 5×10¹⁷-11×10¹⁷ atoms/cm³ and a Young's modulus of 100-120 GPa).

Therefore, during exposure of a device formation process, for example, when the silicon wafer is simple-supported by a total of 6 supporting pins 12 on a wafer stage of a stepper, the silicon wafer has a higher Young's modulus and is harder to sag as compared to a conventional silicon wafer. Since boron is added to silicon and chemical compound precipitation areas 11 of diameters of 0.1 μm are formed in the silicon wafer, when thermal stress occurs, slip can be reduced by effects such as dislocation pinning. Further, gettering sites are formed, thereby enabling creation of a pollution control function in a device process.

As an additive element in molten silicon, boron may be replaced by nitrogen such that a silicon wafer has a nitrogen concentration of 1×10¹⁶ atoms/cm³, or boron may also be replaced by carbon such that a silicon wafer has a carbon concentration of 1×10^{14 atoms/cm}³. As a method for adding nitrogen, argon gas may be replaced by nitrogen gas as the gas in the chamber when a silicon monocrystal is pulled up. The amount of nitrogen gas supplied is such that the nitrogen concentration in a pulled-up silicon monocrystal is 1×10¹⁶ atoms/cm³. Diffusing nitrogen of this concentration in silicon increases the coefficient of elasticity. As a method for adding carbon, instead of boron, carbon may be put into molten silicon when a silicon monocrystal is pulled up. The amount of carbon put into molten silicon is such that the carbon concentration in molten silicon is 1×10¹⁴ atoms/cm³. Adding this amount of carbon in silicon can increase the coefficient of elasticity.

Next, the silicon wafer according to the second embodiment of the present invention is explained with reference to FIG. 3. As shown in FIG. 3, a characteristic of the silicon wafer 10A of the second embodiment is that, instead of forming chemical compound precipitation areas 11 of silicon boride in silicon as in the first embodiment, the solid solution oxygen concentration is 3×10¹⁸ atoms/cm³ and the wafer is formed of a solid solution 13 of silicon and carbon.

When a silicon monocrystal is pulled up by using the Czochralski method, carbon is added to molten silicon in an amount such that the carbon concentration in molten silicon is 1×10¹⁴ atoms/cm³. And the pulling-up condition is such that a solid solution oxygen concentration is 3×10^{18 atoms/cm}³ and a solid solution (interstitial solid solution) 13 of silicon and carbon is formed. Thereby, a silicon monocrystal composed of a solid solution 13 of silicon and carbon is grown. The silicon monocrystal is then wafer-processed. By doing so, a silicon wafer 1 OA is obtained from the solid solution 13 of silicon and carbon, having a solid solution oxygen concentration of 3×10¹⁸ atoms/cm³ and a Young's modulus of 150 GPa. As a result, a wafer having a higher coefficient of elasticity can be obtained as compared to a conventional method. Other configurations, applications and effects are similar to those of the first embodiment, and their explanations are omitted.

It is noted that the foregoing examples have been provided merely for the purpose of explanation and are in no way to be construed as limiting of the present invention. While the present invention has been described with reference to exemplary embodiments, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular structures, materials and embodiments, the present invention is not intended to be limited to the particulars disclosed herein; rather, the present invention extends to all functionally equivalent structures, methods and uses, such as are within the scope of the appended claims.

The present invention is not limited to the above described embodiments, and various variations and modifications may be possible without departing from the scope of the present invention.

What is claimed is:

1. A silicon wafer fabricated from a silicon monocrystal, wherein:
the silicon monocrystal is pulled up from molten silicon by using the Czochralski method;
the molten silicon is added with an additive element; and
the silicon wafer has a solid solution oxygen concentration of equal to or higher than 2×10¹⁸ atoms/cm³ and a chemical compound precipitation area formed by precipitation of a chemical compound of silicon and the additive element.

2. A silicon wafer fabricated from a silicon crystal, wherein:
the silicon monocrystal is pulled up from molten silicon by using the Czochralski method;
the molten silicon is added with an additive element;
the silicon wafer has a solid solution oxygen concentration of equal to or higher than 2×10¹⁸ atoms/cm³; and
the silicon wafer is formed of a solid solution of silicon and the additive element.
